(19) United States
(12) Patent Application Publication
(10) Pub. No.: US 2018/0045793 A1
(43) Pub. Date: Feb. 15, 2018

(54) ELECTRICAL ASSEMBLY FOR MEASURING A CURRENT INTENSITY OF A DIRECT-CURRENT CIRCUIT BY MEANS OF THE ANISOTROPIC MAGNETORESISTIVE EFFECT

(71) Applicant: Magna Powertrain GmbH & Co KG, Lannach (AT)

(72) Inventors: Zoltan HERICS, Sopron-Balf (HU); Csaba NAGYNEMEDI, Wien (AT)

(21) Appl. No.: 15/553,253

(22) PCT Filed: Feb. 5, 2016
(86) PCT No.: PCT/EP2016/052548

§ 371 Date: Aug. 24, 2017

(30) Foreign Application Priority Data
Mar. 3, 2015 (DE) 102015203732.0

(51) Int. Cl. G01R 33/09; G01R 15/20

(52) U.S. Cl. CPC G01R 33/096; G01R 15/205; G01R 33/0005

(57) ABSTRACT

An electrical assembly comprising a DC circuit and a current measuring apparatus for measuring a current intensity of the DC circuit. The DC circuit having a DC source, a positive line and a negative line, the positive line being electrically connected to a positive pole of the DC source and the negative line being electrically connected to a negative pole of the DC source. The current measuring apparatus comprising a measuring element, the positive line and the negative line running parallel to one another at least in a measurement region and the measuring element being arranged in the measurement region, the measuring element being designed in such a manner that it measures a current on the basis of the anisotropic magnetoresistive effect during current flow.

### CROSS-REFERENCE TO RELATED APPLICATIONS

This application is a National Stage of International Application No. PCT/EP2016/052548, filed Feb. 5, 2016 which claims priority to German Application No. 10 2015 203 732.0 filed Mar. 3, 2015. The entire disclosure of each of the above applications is incorporated herein by reference.

### FIELD OF THE INVENTION

The present invention relates to an electrical assembly comprising a DC circuit and a current measuring apparatus for measuring a current intensity of the DC circuit.

### BACKGROUND

This section provides information related to the present disclosure which is not necessarily prior art.

Potential-free current measurement is used in a wide variety of technical fields which deal with electrical energy transmission—and in the field of motor vehicle technology.

A wide variety of energy stores are used in electric and hybrid motor vehicles, in which case the currently probably best-known representatives of energy stores in automotive use are battery systems based on lithium ion secondary batteries.

The use of such a battery system requires complicated battery management in order to ensure the safety, the reliability and the required service life goals, in particular. The most exact knowledge possible of all battery-relevant variables, for example internal resistance, current intensity and voltage, forms the basic prerequisite for successful battery management.

For example, the ageing of a battery can be determined by measuring an internal resistance. The state of charge of a battery can be determined by means of a voltage measurement in combination with a current measurement and the charge removed and/or applied can be determined by means of a current measurement over time.

Current measurement often also plays an important role within the scope of the safety management of a battery system. In this case, current management is used, for example, to monitor safety-relevant functions or to detect faults.

The current is generally measured in this case by
a.) measuring a voltage drop across a non-reactive resistor (shunt) introduced into the circuit
b.) measuring magnetic fields of a conductor through which current flows using a magnetoresistive effect, for example the Hall effect and/or the anisotropic magnetoresistive effect (AMR effect).

The document DE 10 2012 006 269 A1 describes, for example, a sensor arrangement for measuring a current intensity. In this case, the sensor arrangement comprises a current sensor having at least one current recording element which records a load current through an electrical conductor and provides an electrical measurement signal on the basis of this load current.

The current recording element is preferably described as a resistance element in this document, in which case it is explained that it may also be a magnetic field sensor element, however.

DE 43 00 605 C2 describes a sensor chip which operates on the basis of the AMR effect, in particular, and thus measures current in a potential-free manner by recording a magnetic field (a magnetic field gradient). In order to minimize the great sensitivity of the magnetic-field-sensitive sensor system to (homogeneous) interference fields, a magnetic field gradiometer is produced by the specific arrangement of the magnetic-sensitive elements. In order to be able to provide the magnetic field gradient, said document proposes, for example, a U-shaped design of the current conductor through which the current to be measured flows. The disadvantage of this is that the current which normally flows in straight current conductors must be supplied through a U-shaped conductor, which requires an increased outlay on production and installation space, inter alia.

The document DE 198 38 536 A1 discloses an apparatus and a method for forming one or more magnetic field gradients through a straight current conductor at the location of the magnetic field measurement. In this case, a straight current conductor having a recess, for example a slot or a groove, is presented. The magnetic-field-sensitive element, which is in the form of a magnetic field gradiometer, is arranged in the recess. The possibility of arranging two absolute field measuring devices in the recess is also described.

### SUMMARY OF THE INVENTION

This section provides a general summary of the disclosure, and is not a comprehensive disclosure of its full scope or all of its features.

An object of the invention is to present an electrical assembly for determining a current intensity of a DC circuit, which assembly is distinguished by a small installation space requirement and a minimized outlay on components.

The object is achieved by means of an electrical assembly comprising a DC circuit and a current measuring apparatus for measuring a current intensity of the DC circuit, the DC circuit having a DC source, a positive line and a negative line, the positive line being electrically connected to a positive pole of the DC source and the negative line being electrically connected to a negative pole of the DC source, the current measuring apparatus comprising a measuring element, the positive line and the negative line running parallel to one another at least in a measurement region and the measuring element being arranged in the measurement region, the measuring element being designed in such a manner that it measures a current on the basis of the anisotropic magnetoresistive effect during current flow.

According to the invention, the electrical assembly has a DC circuit and a current measuring apparatus.

According to the present invention, the DC circuit comprises a DC source, a positive line and a negative line.

According to the invention, the positive line of the DC circuit is electrically connected to a positive pole of the DC source.

According to the invention, the negative line of the DC circuit is electrically connected to a negative pole of the DC source.

The same current therefore flows through the positive line and the negative line.

According to the invention, the current measuring apparatus is used to contactlessly measure a current intensity of the DC circuit (direct current). For this purpose, it has a measuring element, this measuring element being arranged in a measurement region according to the invention.

According to the invention, the positive line and the negative line run parallel to one another in the measurement region.

The measuring element is designed in such a manner that it measures a current on the basis of the anisotropic magnetoresistive effect during current flow.

As a result of such an electrical assembly according to the invention, the corresponding current intensity of the DC circuit can be determined in a very simple manner during current flow by arranging the measuring element in the measurement region of the DC circuit.

Furthermore, the installation space required in this case is minimized, thus ensuring a high integration density of all individual components.

In addition, the material and/or component requirement, in particular relating to the electrical lines (positive line and/or negative line) and EMC filter measures, is reduced in comparison with the prior art.

A current measurement of high accuracy and high robustness is achieved on account of the use of the anisotropic magnetoresistive (AMR) effect and the arrangement of the positive line and the negative line with respect to one another and with respect to a housing of the electrical assembly, for example.

Developments of the invention are stated in the dependent claims, the description and the accompanying drawings.

The measuring element is preferably arranged in the measurement region above the positive line and the negative line in a side view of the electrical assembly.

Furthermore, the measuring element is preferably arranged in the measurement region between the positive line and the negative line in a plan view of the electrical assembly.

In this case, it is particularly favorable if the measuring element is arranged substantially centrally between the positive line and the negative line in a plan view of the electrical assembly, that is to say the distance between that side edge of the measuring element which faces the positive line and the positive line and the distance between that side edge of the measuring element which faces the negative line and the negative line are substantially the same.

The distance between the positive line and the negative line and the positioning of the measuring element above the positive line and the negative line (vertical position) are determined by the maximum measured current intensity and by the dimensions of the positive conductor and the negative conductor, substantially the cross section thereof.

The current direction in the positive line is preferably opposite the current direction in the negative line.

According to one advantageous embodiment variant, the measuring element has a housing with electrical connections, a semiconductor chip and at least one magnetic-field-sensitive element.

In one particularly preferred embodiment, the measuring element is an AMR sensor.

In order to ensure the function of the assembly according to the invention, the measuring element is arranged on a printed circuit board. The printed circuit board constitutes the carrier of the measuring element and other electrical components and enables the electrical connection between the measuring element and other electrical components. In addition, the printed circuit board constitutes a separation between a low-voltage region (measuring element plane) and a high-voltage region (DC circuit plane).

In another preferred embodiment variant, the positive line and the negative line have a substantially strip-like design. These are, in particular, cuboidal non-ferromagnetic sheet metal parts made of copper or aluminum, for example.

However, the cross section of the positive line and/or negative line need not be square—it may likewise be cylindrical, oval etc.

It is advantageous if the strip-like positive line and the strip-like negative line are arranged symmetrically, mirrored with respect to the vertical axis, at least in the measurement region.

In one advantageous embodiment, the positive line and the negative line are particularly preferably arranged equidistantly in the measurement region.

The DC source is particularly preferably a battery, in particular a battery for a motor vehicle.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows a plan view of an exemplary mechanical assembly according to the invention.

FIG. 2 shows a sectional view of an exemplary mechanical assembly according to the invention.

FIG. 3 schematically shows a plan view of a measuring element, a positive line and a negative line.

FIG. 4 schematically shows a perspective view of a measuring element, a positive line and a negative line.

### DETAILED DESCRIPTION OF THE INVENTION

Example embodiments will now be described more fully with reference to the accompanying drawings.

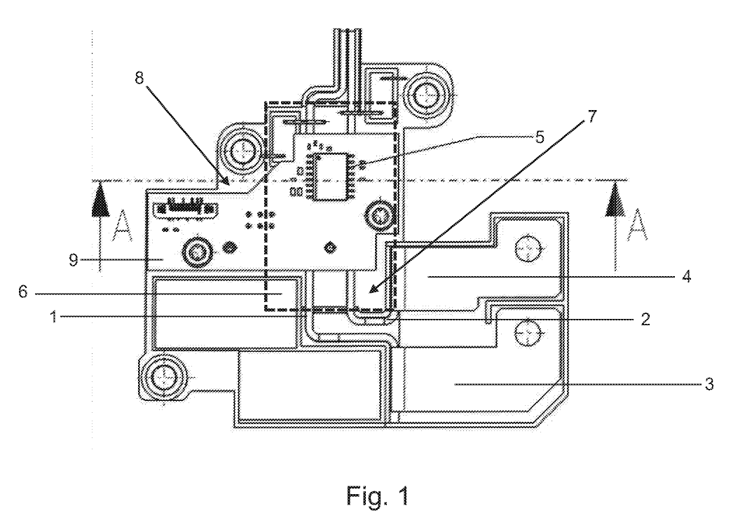

FIG. 1 shows a plan view of an exemplary electrical assembly according to the invention.

The electrical assembly has a DC circuit 7 and a current measuring apparatus 8.

According to the invention, the DC circuit 7 comprises a DC source, a positive line 1 and a negative line 2.

The positive line 1 of the DC circuit 7 is electrically connected to a positive pole 3 of the DC source.

The negative line 2 of the DC circuit 7 is electrically connected to a negative pole 4 of the DC source.

The current measuring apparatus 8 is used to contactlessly measure a current intensity of the DC circuit 7 (direct current). For this purpose, it has a measuring element 5, this measuring element 5 being arranged in a measurement region 6.

The positive line 1 and the negative line 2 run parallel to one another in the measurement region 6. In addition, the positive line 1 and the negative line 2 are arranged equidistantly in the measurement region 6.

The measuring element 5 is designed in such a manner that it measures a current on the basis of the anisotropic magnetoresistive effect during current flow.

In the plan view of the electrical assembly illustrated in FIG. 1, the measuring element 5 is arranged centrally in the measurement region 6 between the positive line 1 and the negative line 2 on a printed circuit board 9.

In the illustrated embodiment of the electrical assembly according to the invention, the measuring element 5 at least partially covers the positive line 1 and the negative line 2 in the measurement region 6 in a plan view of the electrical assembly.

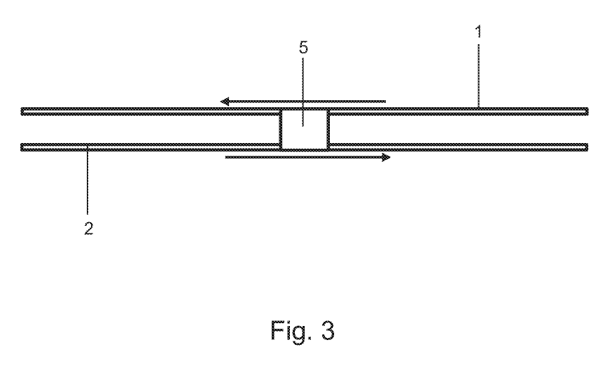

FIG. 3 likewise schematically illustrates the arrangement of the measuring element 5 in the measurement region 6 between the positive line 1 and the negative line 2. The positive line 1 and the negative line 2 run parallel to one another in the measurement region 6. The positive line 1 and the negative line 2 are equidistant in the measurement region 6.

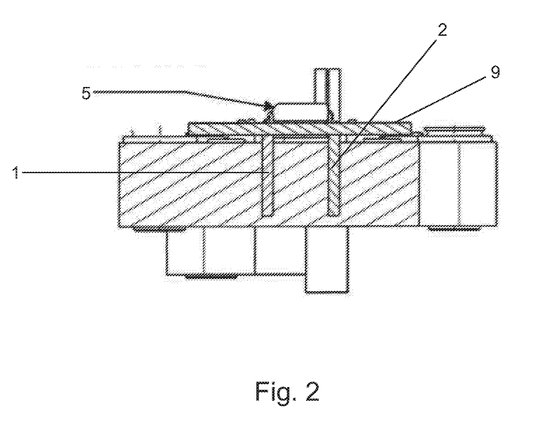

FIG. 2 illustrates a side view of an exemplary electrical assembly according to the invention. The side view in this figure (FIG. 2) shows a sectional plane along the line A-A illustrated in FIG. 1.

The positive line 1 and the negative line 2 are also illustrated here, this time in cross section.

In this case, the positive line 1 and the negative line have a strip-like design and are arranged in a horizontally running but vertical manner, with the result that the surfaces of the strips are opposite one another on the left and right and the narrow sides of the strips point up and down. In addition, the positive line 1 and the negative line 2 are arranged equidistantly in the measurement region 6 and run parallel to one another. The entire surfaces of the strips are therefore arranged parallel to one another in the measurement region.

In the illustrated side view of the electrical assembly, the measuring element 5 is arranged in the measurement region 6 above the positive line 1 and the negative line 2 on the printed circuit board 9.

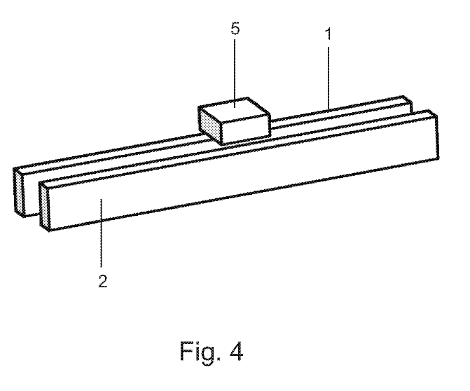

FIG. 4 likewise schematically shows the arrangement of the measuring element 5 in the measurement region 6 above the positive line 1 and the negative line 2. The positive line 1 and the negative line 2 run parallel to one another in the measurement region and are equidistant.

FIG. 3 schematically shows a plan view of a measuring element 5, a positive line 1 and a negative line 2. The arrows running in opposite directions, as illustrated in FIG. 3, indicate the current direction in the positive line 1 and the negative line 2.

The current direction in the positive line is opposite the current direction in the negative line.

FIG. 4 schematically shows a perspective view of a measuring element 5, a positive line 1 and a negative line 2. In this case, the positive line 1 and the negative line 2 have a strip-like design, substantially in the form of an elongated cuboid. They are equidistant and run parallel to one another.

### LIST OF REFERENCE SYMBOLS

1 Positive line

2 Negative line

3 Positive pole

4 Negative pole

5 Measuring element

6 Measurement region

7 DC circuit

8 Current measuring apparatus

9 Printed circuit board

1. An electrical assembly comprising a DC circuit and a current measuring apparatus for measuring a current intensity of the DC circuit, the DC circuit having a DC source, a positive line and a negative line, the positive line being electrically connected to a positive pole of the DC source and the negative line being electrically connected to a negative pole of the DC source, the current measuring apparatus comprising a measuring element,
wherein the positive line and the negative line run parallel to one another at least in a measurement region, and the measuring element arranged in the measurement region, the measuring element being designed in such a manner that it measures a current on the basis of the anisotropic magnetoresistive effect during current flow.

2. The electrical assembly as claimed in claim 1,
wherein the measuring element is arranged in the measurement region above the positive line and the negative line in a side view of the electrical assembly.

3. The electrical assembly as claimed in claim 1,
wherein the measuring element is arranged in the measurement region between the positive line and the negative line in a plan view of the electrical assembly.

4. The electrical assembly as claimed in claim 3,
wherein the measuring element is arranged substantially centrally between the positive line and the negative line in a plan view of the electrical assembly.

5. The electrical assembly as claimed in claim 1,
wherein the current direction in the positive line is opposite the current direction in the negative line.

6. The electrical assembly as claimed in claim 1,
wherein the measuring element has a housing with electrical connections, a semiconductor chip and at least one magnetic-field-sensitive element.

7. The electrical assembly as claimed in claim 1,
wherein the measuring element is an AMR sensor.

8. The electrical assembly as claimed in claim 1,
wherein the measuring element is arranged on a printed circuit board.

9. The electrical assembly as claimed in claim 1,
wherein the positive line and the negative line have a substantially strip-like design.

10. The electrical assembly as claimed in claim 9,
wherein the positive line and the negative line are arranged symmetrically, mirrored with respect to the vertical axis, at least in the measurement region.

11. The electrical assembly as claimed in claim 1,
wherein the positive line and the negative line are arranged equidistantly in the measurement region.

12. The electrical assembly as claimed in claim 1,
wherein the DC source is a battery.
